(19) United States
(12) Patent Application Publication
(10) Pub. No.: US 2014/0004653 A1
(43) Pub. Date: Jan. 2, 2014

(54) Pseudo-Schottky photovoltaic cell by wet-printing a conductive paint

(71) Applicants: Blaise L. Corbett, King George, VA (US); William P. Adams, Mechanicsville, VA (US); Kevin D. Collier, Mount Carmel, TN (US)

(72) Inventors: Blaise L. Corbett, King George, VA (US); William P. Adams, Mechanicsville, VA (US); Kevin D. Collier, Mount Carmel, TN (US)

(73) Assignee: United States of America via Secr. of Navy, Arlington, VA (US)

(21) Appl. No.: 11/447,513

(22) Filed: May 30, 2006

Related U.S. Application Data
(60) Provisional application No. 60/751,616, filed on Dec. 7, 2005.

(51) Int. Cl. H01L 31/18; H01L 31/108

(52) U.S. Cl. 438/92; 136/255; 257/E31.065

(57) ABSTRACT

Various embodiments relate to a functional low cost photovoltaic (PV) cell (e.g., solar cell) and a method for the large scale production of the device. The manufacturing method to produce a pseudo-Schottky photovoltaic (PSPV) cell, includes depositing a metal contact on a reverse side of the wafer; superposing a mask on an obverse side of the wafer; disposing a conductive paint to the obverse side of the wafer; removing the mask on the obverse side of the wafer; and attaching electrical conduction leads between the paint and the metal contact.

### CROSS REFERENCE TO RELATED APPLICATION

The invention claims priority to and incorporates by reference in its entirety Provisional U.S. Patent Application 60/751,616 filed Dec. 7, 2005 titled “Continuous Wet-Printed Pseudo-Schottky Photovoltaic Cell Using a Conductive Paint” to Blaise L. Corbett, William P. Adams and Kevin D. Collier.

### STATEMENT OF GOVERNMENT INTEREST

The invention described was made in the performance of official duties by one or more employees of the Department of the Navy, and thus, the invention herein may be manufactured, used or licensed by or for the Government of the United States of America for governmental purposes without the payment of any royalties thereon or therefor.

### BACKGROUND

Current techniques for photovoltaic (PV) cell production center around the use of either p-n junction models or to a lesser extent Schottky barrier diode models. The p-n junction models are generally the most efficient model of the PV cell model families. The efficiency of the PV cell is determined by the ratio of power produced by the PV cell to power incident on the PV cell.

Generally accepted parameters for incident solar power are approximately 1000 W/m² (watts per square meter) at the equator and approximately 500 W/m² in northern latitudes at maximum vertical angle. Actual incident power on the active regions of a PV cell is contingent on weather conditions, region of exposure, as well as the structural environment.

The p-n junction models are the most common and vary from single to multiple layer junctions and include the newer thin film technologies. These types of PV cells are dual carrier devices; that is they take advantage of excess electrons produced in the p-type region and holes (positive carriers) generated in the n-type region. The total carrier displacement makes up the current delivered by the device.

The typical efficiency of this type of cell can range from 5% to 11% and are dependent on the number of junction layers and the materials used. Higher efficiencies can be obtained using concentrator cells, which depend heavily on optics. The models and techniques for the production of this type of PV cell are established and well known within the art and will not be discussed here but can be found in Solid State Electronic Devices by B. Streetman, Prentice Hall, ©1995; and Semiconductor Optoelectronic Devices, 2^{nd} ed. by P. Bhattacharya.

A less commonly used model for PV cell construction is the Schottky barrier model. The Schottky barrier PV is a minority carrier device; i.e., having only one carrier type, either holes or electrons, that represents the current produced by the active cell. The Schottky barrier PV cell takes advantage of the electrical effects induced by differing work functions of a metal and semiconductor material when they are bonded.

By appropriately accounting for the work functions, the profile doping of the semiconductor material, the solubility of the applied metals within the semiconductor, and appropriate use of fabrication techniques, a Schottky junction can be formed that can be effectively used as a PV cell.

For an n-type semiconductor material in the Schottky junction, a metal may be selected with a higher metal work function relative to the semiconductor work function. For a p-type semiconductor, the selected metal may possess a lower metal work function relative to the semiconductor work function. The primary advantage of the Schottky model is simplicity of manufacture and therefore decreased costs. The disadvantage is that the Schottky model cannot approach the efficiency of the more complex p-n junction cell model. Typical efficiencies are 4% to 6%. Both p-n junction and Schottky models require essentially the same type of production facilities and materials.

### SUMMARY

Various exemplary embodiments provide a method for producing a Pseudo-Schottky photovoltaic (PSPV) cell. The procedures include depositing a metal contact on a reverse side of the wafer; superposing a mask on an obverse side of the wafer; disposing a conductive paint to the obverse side of the wafer; removing the mask on the obverse side of the wafer; and attaching electrical conduction leads between the paint and the metal contact.

### BRIEF DESCRIPTION OF THE DRAWINGS

These and various other features and aspects of various exemplary embodiments will be readily understood with reference to the following detailed description taken in conjunction with the accompanying drawings, in which like or similar numbers are used throughout, and in which:

FIG. 1 is a cross-section diagram of the prototype PSPV cell;

FIG. 2 is a flowchart showing process operations for producing the PSPV cell;

FIG. 3A is a mask configuration used for the prototype;

FIG. 3B is an example finished prototype product; and

FIG. 4 is a wafer handler block diagram.

### DETAILED DESCRIPTION

With increasing energy costs and a limited supply of fossil fuels, alternative means of producing energy need to be developed and exploited. One of these alternatives that has been slowly gaining acceptance is solar energy conversion. Two methods of direct solar energy conversion exist, passive and active. Passive conversion makes use of thermal collection techniques that may be simple in design and effective for limited applications such as heating water. Active energy conversion may use photovoltaic (PV) cells for the direct conversion from solar energy to electricity.

Photovoltaic cells employ a number of design models that vary in efficiency but they all have in common the use of semiconductor material. Another common factor is that the current technologies involve relatively expensive processes and material. Many of the current technologies employ or incorporate toxic, corrosive and/or environmentally hazardous materials.

These factors translate into a higher energy cost relative to fossil fuels. The purpose of this disclosure is to introduce both a fabricated prototype of a functional PV or solar cell and a notional concept for the large scale production of said device, such that the cell can be constructed both at low-cost and with minimal environmental impact.

The embodiments presented herein of a conceptual model and prototype represents a derivation of the Schottky PV model. The embodiments propose a Pseudo-Schottky PV (PSPV) model, rather than a true Schottky model. The PSPV remains a minority carrier device and takes advantage of a statistically different work function of the conductive paint relative to the work function of the semiconductor.

The prototype developed is a PSPV model lacking a pure metal with a well defined work function for a top contact that defines a true Schottky barrier contact. Instead, the prototype uses a specially formulated, highly conductive paint produced by Unitech Corporation. An example is Unitech paint type #10103, which does not exhibit environmental or health concerns and is relatively low-cost compared to competing materials.

The paint is a water-based polymer formulation mixed with a proprietary combination of conductive constituents that effectively makes the paint highly conductive when properly applied to a surface and permitted to dry. In particular, the polymer composing the paint does not electrically insulate the dried material. The paint mixture, though conductive, lacks a well defined work function.

Conceivably, this paint mixture work function could be statistically derived knowing the characteristics of the constituent materials. However, the inventors are, at the time of filing, unaware of any such efforts including by the representatives at Unitech. The characteristic of the work function was therefore determined by applying the prototype production process to both p-type and n-type semiconductor wafers to determine which produced an active device.

The work function of the Unitech material was determined to be comparatively greater than the work function of the semiconductor material used. In the applications considered, extrinsic Silicon served as the semiconductor material. Hence, the PSPV cell prototype used n-type material.

The materials and equipment used in the production of the PSPV tested include the following: (a) one 3-inch n-type silicon wafer (heavily doped n⁺); (b) 2 ml of Unitech paint type #10103; (c) less than 1 g of aluminum; (d) metal sputtering equipment; (e) sintering oven; (f) Testors® Brand propellant powered airbrush; (g) masking tape; (h) copper connecting wire; and (i) plexiglas case.

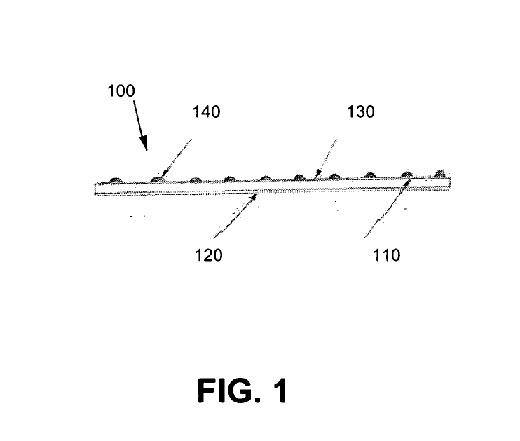

FIG. 1 shows a cross-section diagram of the prototype PSPV cell 100. A silicon semiconductor wafer 110 includes a metal layer for an ohmic contact 120 on the reverse side and a thin silicon oxide (SiO₂) layer 130 on the obverse side. Superposed on the SiO₂ layer are grid lines 140 of conductive paint.

There are a number of process considerations that were taken into account in order to fabricate the prototype. Because of the prototype nature of the example, expedience and material availability were considered, and adjustments were performed accordingly.

Process considerations for improvement of the device are summarized later in this disclosure. Artisans of ordinary skill will recognize that the optimization procedures to be detailed as well as those not specifically listed can be incorporated into the fabrication process without deviating from the intent of the original outlined process.

The wafer material used to fabricate the prototype PSPV cell 100 is highly doped n⁺-type silicon. Doping level of the semiconductor material has a direct effect on the carrier mobilities and diffusion lengths of the carriers at ambient temperature.

The carrier mobility is inversely proportional to the impurity concentration of the intrinsic material. This is due to the effects of lattice scattering. Generally, a moderate level of doping is preferred. The prototype used a highly doped wafer due not only to its availability, but also to overcome some difficulties in the fabrication of an ohmic contact 120 on the wafer's reverse side.

Due to limited facilities and constrained material availability, aluminum was sputtered to deposit the ohmic contact 120 on the reverse side of the device wafer 110. Normally an aluminum contact is not the optimal contact when working with n-type semiconductor material. The preferred material is gold with a small amount of antimony.

Because a highly doped n⁺ semiconductor was employed, an aluminum reverse contact 120 on the semiconductor wafer is used. Had a p⁺ semiconductor been employed, aluminum could still be used as a contact, but a sintering procedure would have been necessary to produce a good ohmic contact.

The depletion region formed between the aluminum reverse contact 120 and the semiconductor device wafer 110 is an extremely narrow layer. Hence, carriers can overcome the region by a “tunneling” process. The use of the aluminum reverse contact 120 may diminish efficiency as compared to gold, but the output should be sufficient for operation.

In an effort to increase the efficiency of the PSPV prototype cell 100, an oxide layer 130 was grown on the surface of the silicon substrate that represents a device wafer 110. This oxide layer 130 is necessary to reduce the number of surface states on the device wafer 110 that act to trap carriers before they can reach the collector grid lines 140. These layers tend to be very thin (<20 nm) and may be grown at a controlled rate at relatively low temperatures (<300° C.).

A sintering oven set at 220° C. for 10 minutes was used to grow the thin oxide layer 130 on the device wafer 110 using the silicon substrate as the source material. Other techniques for growing an oxide layer 130 are common and well known within the art, so these will not be discussed further.

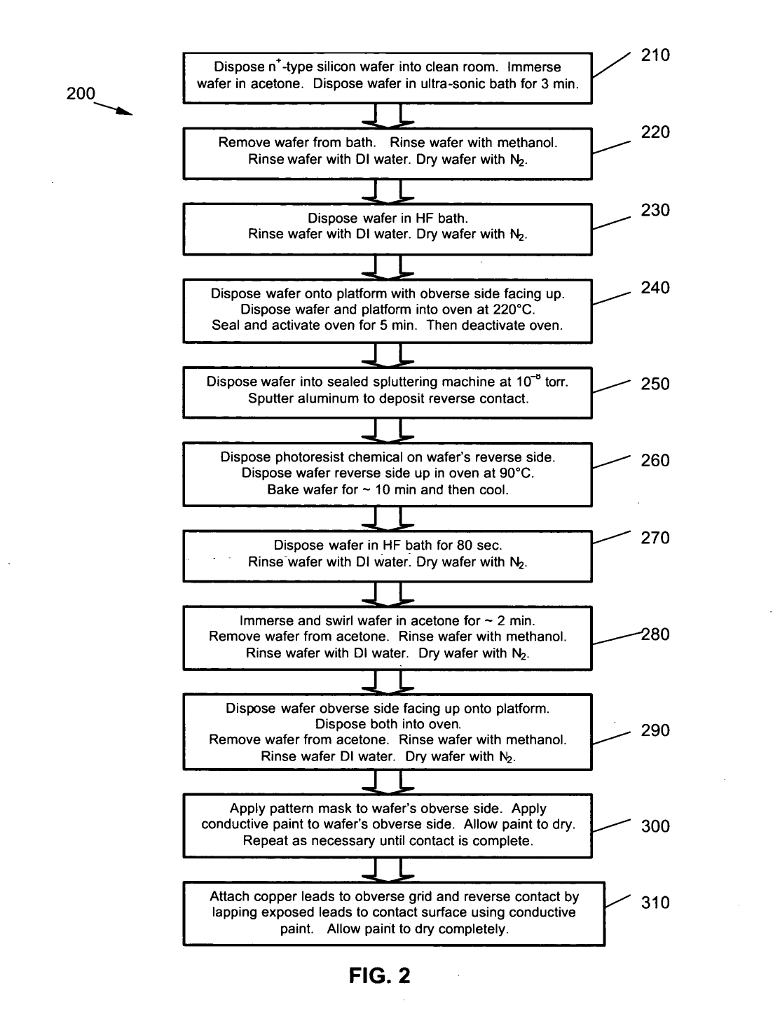

The following procedure, as provided in FIG. 2, is a description of the operational steps taken during the fabrication of the prototype cell. Artisans of ordinary skill will understand that the description only serves to outline the steps specifically taken during prototype fabrication and modifications to the steps can be made without departing from the spirit of the original concept. The procedure 200 may incorporate the listed steps below:

First, at step 210, an n⁺-type mono-crystalline silicon device wafer 110 was brought into a clean room. All precautions to prevent accidental introduction of contaminants were taken.

Second, continuing at step 210, the device wafer 110 is immersed in a bowl of an organic solvent, such as acetone (CH₃COCH₃) and placed in an ultra-sonic bath for 3 minutes.

Third, at step 220, the device wafer 110 is removed from the bath and rinsed with methanol (CH₃OH) followed by rinsing with deionized (DI) water. The device wafer 110 is then dried with a nitrogen (N₂) gas gun.

Fourth, at step 230, the device wafer 110 is then placed in a hydrofluoric (HF) acid bath for one minute to remove the oxide layer that naturally forms thereon. The device wafer 110 is then rinsed with deionized water and dried with a nitrogen gas gun.

Fifth, the device wafer 110 is then placed on a clean lint free towel.

Sixth, at step 240, the device wafer 110 is disposed with the polished obverse side facing up onto a larger support wafer or platform. The two wafers are then placed into a laboratory oven set to a temperature of 220° C. The oven is sealed and activated. Upon reaching 220° C. the oven operates for five minutes and then is deactivated.

Seventh, upon oven temperature reaching 100° C., the oven door is opened slightly to facilitate cooling.

Eighth, after cooling and removal from the platform, the device wafer 110 is placed into a spluttering machine for deposition of the aluminum reverse contact 120.

Ninth, at step 250, placed properly into the spluttering machine, the machine is sealed and pressure reduced to a partial vacuum, e.g., 10⁻⁸ torr. Although sputtering in this application requires a sub-atmospheric pressure, other partial vacuum pressures may be used without affecting the scope of the invention. The aluminum may then be sputtered to reverse side of the device wafer 110 to produce the reverse contact 120.

Tenth, the device wafer 110 is removed from the spluttering device and inspected. After inspection, the device wafer 110 is placed in a protective case and removed from the clean room environment.

The device wafer 110 now has a thick oxide layer on the obverse face. This layer should be removed without damaging the aluminum reverse contact 120. A photoresist chemical is disposed on the wafer's reverse side to protect the aluminum reverse contact 120. A photoresist material such as Shipley S1818 may be used for this purpose.

Eleventh, at step 260, the device wafer with photoresist applied is placed reverse side up in an oven set at 90° C. and baked for approximately ten minutes. This hardens the photoresist against chemicals such as hydrofluoric acid. The device wafer 110 is then removed from the oven and permitted to cool.

Twelfth, at step 270, the device wafer 110 is then placed in a hydrofluoric acid bath for 80 seconds to remove the thick oxide layer that formed on the wafer's obverse side during the spluttering process. The device wafer 110 is then rinsed with deionized water and dried with a nitrogen gas gun.

Thirteenth, at step 280, the device wafer 110 is immersed in a bowl of acetone and swirled for approximately two minutes to remove the photoresist.

Fourteenth, continuing at step 280, the device wafer 110 is removed from the bowl and rinsed with methanol followed by rinsing with deinionized water. The device wafer 110 is then dried with a nitrogen gas gun.

Fifteenth, at step 290, the device wafer 110 is disposed with the polished obverse side facing up onto the larger support wafer or platform. The two wafers are then placed into a laboratory oven set to a temperature of 220° C. The oven is sealed and activated:

Upon reaching 220° C., the oven operates for 5 minutes and then is deactivated. This effectively restores the thin oxide layer 130 on the contact (obverse) side of the device wafer 110.

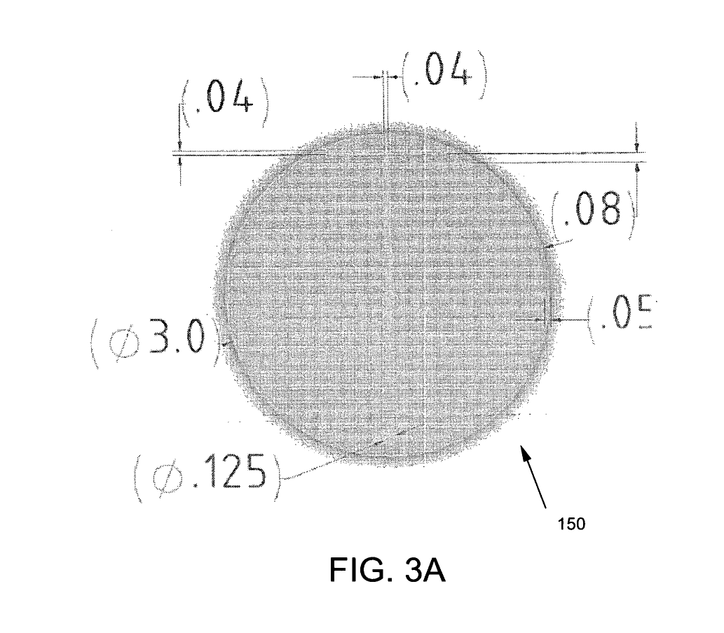

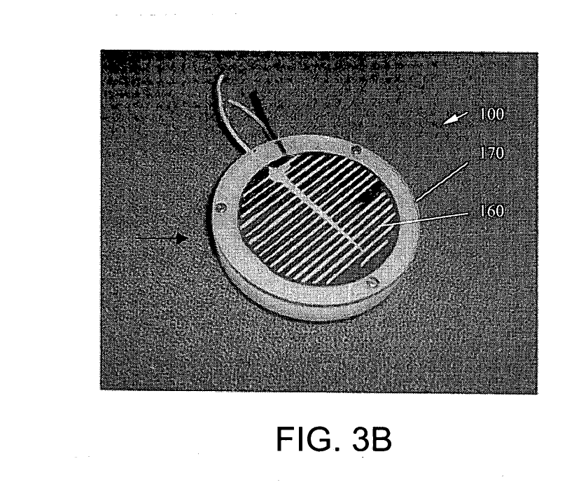

Sixteenth, a number of grid masking techniques were investigated for the device wafer 110. An orthogonal grid masking-tape pattern mask 150 is cut and applied to the obverse side of the wafer 110. FIG. 3 shows the mask configuration used for the prototype.

Seventeenth, at step 300, a propellant model airbrush is used to apply the Unitech conductive paint to the wafer's obverse surface. The paint is sprayed over the wafer 110 and the mask 150 and allowed to dry for five minutes. This procedure may be repeated until a complete contact is produced. These operations may be performed at room temperature and pressure.

Eighteenth, the masking tape is removed to leave a grid pattern 160, shown in FIG. 3A. A second mask is applied to create a tapered center contact. The paint is again sprayed over the wafer's obverse side and mask and allowed to dry for ten minutes prior to removal of the mask 150. This procedure may also be performed at room temperature and pressure.

Nineteenth, at step 310, copper leads are attached to both the obverse grid lines 140 and the reverse contact 120 by lapping the exposed leads to the contact surface using the conductive paint. The paint may then be allowed to dry completely.

Twentieth, the cell 100 is placed into a 3.5-inch diameter cylinder made out of ⅛^{th} inch Plexiglas and a nylon collar 170 to protect the cell during transportation and testing. As shown in FIG. 3A, the testing leads of the cell 100 may be secured by the collar 170 to prevent damage during testing.

In the results, the finished cell 100 in the sample was somewhat rough, as shown in FIG. 3B. The contacts were not very smooth, and there was some adhesive still stuck to the device wafer 110 that would be difficult to remove without damaging the cell 100.

The prototype cell 100 was tested under fluorescent lighting and incandescent lighting. Both types of light sources showed increased levels of voltage and current relative to dark reactions. The incandescent lighting provided by a small flashlight induced an active power output of 0.093 mW. Exposing the cell 100 to ambient sunlight resulted in a total power output of approximately 0.15 mW.

The calculated efficiency of the cell 100 is slightly less than 0.25%. The low efficiency of the cell can be attributed to a number of factors. Some of these factors would be the rough collector grid, the remaining adhesive acting as a filter, the aluminum reverse contact not being truly ohmic, and the fact that it was tested while in the Plexiglas case, which would act as a filter.

The prototype cell might not exhibit high efficiency. However, there are a number of immediately available material and process improvements to dramatically increase the efficiency of the cell, preferably to at least 1% efficiency. They procedures are as follows:

First, moderately doped n-type wafer may be utilized for the substrate. This should improve the carrier velocity and the diffusion length.

Second, a poly-crystalline wafer could be used to improve carrier response.

Third, the reverse contact may incorporate gold alloy with a small percentage of antimony. This will permit a better ohmic contact that improves efficiency over the cell using aluminum.

Fourth, the oxide layer would have a calibrated growth for specific optimal thickness.

Fifth, an electrostatic mask may be used to dispose the contacts onto the wafer surface, or else a different printing process with finer control may be used.

Sixth, Unitech product #10150 or similar product specifically formulated for direct metal surface contact may be incorporated. This could result in a stronger bond of the collector grid lines 140 to the surface of the semiconductor wafer 110.

Seventh, a thin polymer coating may be applied to the surface of the PSPV cell 100 to protect the contacts in place of the Plexiglas cover 170.

The following description is one possible inception of mass production manufacturing of a PSPV cell. Depending on the formulation of the conductive paint and the associated characteristic work function, either a p-type or an n-type semiconductor wafer would be used in this process. The conductive paint in the prototype is one produced by Unitech Corporation, but that selection of the paint is not absolutely required.

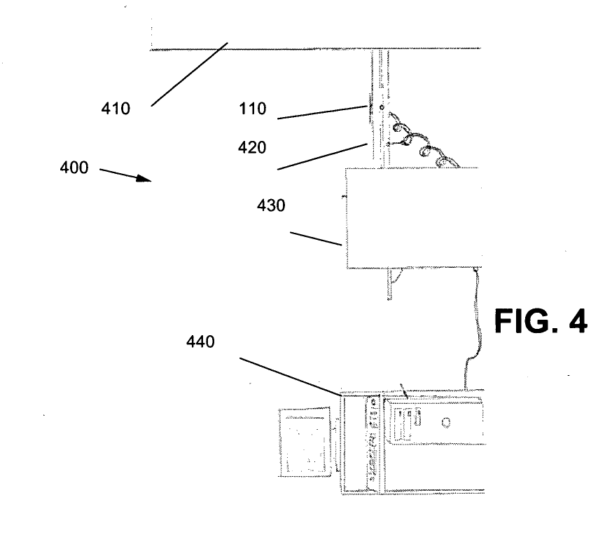

FIG. 4 shows a process assembly 400, including a wafer handler 410. The wafers 110 in the handler 410 have already moved through a pre-fabrication process where the wafer 110 has received an ohmic reverse contact 120 of the appropriate metal and has already had a thin oxide layer 130 grown onto the wafer surface. The wafer handler 410 stores the prepared wafers in a sealed environment and may also have an inert gas introduced to allow long term storage of the discs with minimal oxidation growth.

The wafer handler 410 may select and load the wafer 110 onto a feeding mechanism 420 to a wafer printer 430. The printer 430 optimally may be similar in function to common ink jet printers. This allows for fine detail control during the application of the collector grid, as well as consistent print characteristics such as width, length and line height.

The printer 430 is connected to a control computer 440 that handles the application used to design the collector grid lines 140 as well as to send commands to the wafer handler 410 and the printer 430 during the fabrication procedure.

The collector grid application procedure is described as follows:

First, the prepared wafer 110 is selected from the wafer-handling unit 410 and placed on the printer feed mechanism 420.

Second, the printer feed mechanism 420 brings the wafer 110 into the printer 430 and guides the wafer 110 toward and past the printing heads.

Third, the printer 530 applies the conductive paint to produce the grid lines 140 according to the desired pattern sent from the computer control station 440.

Fourth, the wafer 110 is then conveyed to a drying area and the process can be repeated.

Augmentation processes may incorporate reflective coatings and contact colors. Because PV cells are expected to operate in a wide variety of environmental conditions, most cells incorporate some form of coating to either enhance or reduce reflection of ambient light. Such methods range from applied coatings with color filtering, metal deposition such as a thin layer of gold on an active surface, oxide coatings grown epitaxially on the active surface or lenses with optical properties.

This is done primarily to determine the most efficient active state of the PV cell in given ambient light conditions and temperatures. Some frequencies of light contribute energy to the cell in the form of heat instead of output power and design considerations are made to reduce the incidence of these frequencies on the wafer surface. The PV cell is more efficient when cool. This heat affects the efficiency through both lattice scattering and higher contact resistance.

Addition of a colored dye into the conductive paint represents potential enhancement for the printed cell. The color would be selected based on the intended use and location of the cell. The overall effect of the added dye will be small, but cells are generally not very efficient despite the type and even a small enhancement is preferred to none.

Advantages: The proposed PSPV cell offers some intriguing advantages if properly developed. The PSPV is a green (i.e., environmentally cognizant) solution to PV cell manufacturing. A printed collector utilizing a product such as offered by Unitech eliminates the use of heavy metals for the top contact such as chromium.

By reducing the number of surface etchings and metal depositions you reduce the volume of harmful chemicals such as HF acid and acetone that are used in the fabrication process. This reduces both the volume and cost of storage and disposal of consumed chemicals.

The amount of energy required to produce each cell is greatly diminished leading to a decreased use of energy and therefore a reduction of particulate and geothermal pollution at the utility source.

There is no traditional masking and therefore materials such as glass and photo developing chemicals are eliminated.

There is less solid waste. Materials, such as glass masks, wafers with poor contact structures, or wafers that have otherwise been disposed of due to a glitch in the fabrication process, typically end up in land fills. Using the proposed process, there is no longer a glass mask used and unless the wafer 110 is structurally damaged, the contact area can be cleaned and reused.

With the simplified process, there are fewer man-hours needed per cell for production. Manufacturing time is one of the most significant drivers of production cost. For the prototype, manufacturing time was less than 5% the manufacturing time required to produce a traditional Schottky cell. In mass production this cost advantage could significantly offset the disadvantage of lower cell efficiency.

Design and modification of the collector grid pattern and color can also be performed on the fly from the computer terminal. This leads to faster prototype testing and shorter testing to production times. Again, for unsatisfactory grid pattern characteristics, the wafer can be cleaned and reused.

Alternatives: The field of solar electric techniques is a growing one and there is no doubt that as energy costs continue to increase, better methods of harvesting that energy will evolve and current technologies will become less expensive to implement.

Unfortunately, the progress being made to reduce the costs of traditional solar cell technologies has been slow, and new ideas to rejuvenate the field have only gradually surfaced. The most promising technology is the thin film cell that has the advantage of less material use but nonetheless suffers from the significant costs to produce the cell. The inventors of the proposed PSPV cell have found no similar alternative to those described herein.

The above disclosure outlines the process used to fabricate a Pseudo-Schottky Photovoltaic Cell as a prototype. The prototype exhibited sufficient activity during testing to show the value of the concept in terms of future development. Additionally, a brief description of process improvements that could be applied to the prototype was given.

A notional process was also outlined in this disclosure with the objective of introducing the techniques that could be employed toward mass production of the cell. Additional considerations for improving the performance of a PSPV cell were given in a section on process augmentation.

With the significant energy demands throughout the world on the increase and the concern of a shortage of traditional fuel sources, an increased reliance on non-traditional sources of energy is inevitable. The single greatest factor retarding the adoption of solar energy has not been the reliability of the technology but has been the significant cost of producing PV cells. The invention disclosed in this document may reduce the cost of this type of energy source.

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments.

1. A manufacturing method to produce a pseudo-Schottky photovoltaic (PSPV) cell, the method comprising:
providing a doped silicon wafer having an obverse side and a reverse side;
sintering the wafer to expose the obverse side in an oven by raising temperature to 220° C. and maintaining for five minutes, thereby producing respective first and second silicon-oxide layer on the obverse and reverse sides of the wafer;
polishing the first silicon-oxide layer on the obverse side to uniform thickness;
removing the second silicon-oxide layer on the reverse side;
applying a first photoresist on the obverse side;
depositing a metal contact on the reverse side, causing a third silicon-oxide layer on the obverse side;
applying a second photoresist on the reverse side;
removing the third silicon-oxide layer on the obverse side;
sintering the wafer to expose the reverse side in the oven at 90° C. for about ten minutes, thereby causing a fourth silicon-oxide layer on the obverse side;
removing the first and second photoresists on the respective obverse and reverse sides;
sintering the wafer to expose the obverse side in the oven raising to 220° C. and maintaining for five minutes;
superposing a grid mask on the obverse side;
disposing a conductive paint onto the obverse side;
removing the grid mask on the obverse side to form a collector grid composed of the conductive paint deposited on the obverse side; and
attaching first and second electrical conduction leads respectively to the collector grid and the metal contact to form the PSPV cell.

2. The method according to claim 1,
wherein the wafer is doped as an n-type wafer, and the metal contact is composed of gold doped with antimony.

3. The method according to claim 1,
wherein the wafer is doped as an n⁺-type wafer, and the metal contact is composed of aluminum.

4-5. (canceled)

6. The method according to claim 1, further comprising subsequent to attaching electrical conduction leads:
disposing a polymer coating to the obverse and reverse sides of the wafer.

7-10. (canceled)

11. The method according to claim 1, wherein the mask is composed of an electrostatic mask.

12. The method according to claim 1, wherein the wafer is a poly-crystalline silicon wafer.

13-20. (canceled)

21. The method according to claim 1, further comprising subsequent to attaching electrical conduction leads:
disposing a polymer coating to the collector grid.

22-23. (canceled)

24. The method of claim 3, wherein depositing the metal contact comprises cooling the wafer to 100° C. and sputtering aluminum onto the reverse side at sub-atmospheric pressure.

25. The method of claim 1, wherein disposing the conductive paint on the obverse side comprises spraying thereon with a propellant model air-brush.

26. The method of claim 1, wherein disposing the conductive paint on the obverse side comprises printing thereon with a wafer printer.

27. A manufacturing method to produce a pseudo-Schottky photovoltaic (PSPV) cell, the method comprising:
providing an n⁺-type doped silicon wafer having an obverse side and a reverse side;
sintering the wafer to expose the obverse side in an oven by raising temperature to 220° C. and maintaining for five minutes, thereby producing respective first and second silicon-oxide layer on the obverse and reverse sides of the wafer;
polishing the first silicon-oxide layer on the obverse side to uniform thickness;
removing the second silicon-oxide layer on the reverse side;
applying a first photoresist on the obverse side;
depositing an aluminum contact on the reverse side, causing a third silicon-oxide layer on the obverse side;
applying a second photoresist on the reverse side;
removing the third silicon-oxide layer on the obverse side;
sintering the wafer to expose the reverse side in the oven at 90° C. for about ten minutes, thereby causing a fourth silicon-oxide layer on the obverse side;
removing the first and second photoresists on the respective obverse and reverse sides;
sintering the wafer to expose the obverse side in the oven raising to 220° C. and maintaining for five minutes;
superposing a grid mask on the obverse side;
disposing a conductive paint onto the obverse side;
removing the grid mask on the obverse side to form a collector grid composed of the conductive paint deposited on the obverse side; and
attaching first and second electrical conduction leads respectively to the collector grid and the aluminum contact to form the PSPV cell.

28. A manufacturing method to produce a pseudo-Schottky photovoltaic (PSPV) cell, the method comprising:
providing an n-type doped silicon wafer having an obverse side and a reverse side;
sintering the wafer to expose the obverse-side in an oven by raising temperature to 220° C. and maintaining for five minutes, thereby producing respective first and second silicon-oxide layer on the obverse and reverse sides of the wafer;
polishing the first silicon-oxide layer on the obverse side to uniform thickness;
removing the second silicon-oxide layer on the reverse side;
applying a first photoresist on the obverse side;
depositing metal contact on the reverse side, causing a third silicon-oxide layer on the obverse side;
applying a second photoresist on the reverse side;
removing the third silicon-oxide layer on the obverse side;
sintering the wafer to expose the reverse side in the oven at 90° C. for about ten minutes, thereby causing a fourth silicon-oxide layer on the obverse side;
removing the first and second photoresists on the respective obverse and reverse sides;
sintering the wafer to expose the obverse side in the oven raising to 220° C. and maintaining for five minutes;
superposing a grid mask on the obverse side;
disposing a conductive paint onto the obverse side;
removing the grid mask on the obverse side to form a collector grid composed of the conductive paint deposited on the obverse side; and
attaching first and second electrical conduction leads respectively to the collector grid and the aluminum contact to form the PSPV cell.
